(19) United States
(12) Patent Application Publication
(10) Pub. No.: US 2025/0280621 A1
(43) Pub. Date: Sep. 4, 2025

(54) PASSIVATION METHOD, CELL, AND AUXILIARY PASSIVATION DEVICE FOR IMPLEMENTING PASSIVATION METHOD

(71) Applicant: LAPLACE RENEWABLE ENERGY TECHNOLOGY CO., LTD., Shenzhen (CN)

(72) Inventors: Guanxuan LIU, Shenzhen (CN); Tairong ZHU, Shenzhen (CN); Wu ZHANG, Shenzhen (CN)

(73) Assignee: LAPLACE RENEWABLE ENERGY TECHNOLOGY CO., LTD., Shenzhen (CN)

(21) Appl. No.: 18/759,459

(22) Filed: Jun. 28, 2024

(30) Foreign Application Priority Data
Mar. 4, 2024 (CN) 202410245192.6

(51) Int. Cl. H01L 31/18; H01L 31/0216

(52) U.S. Cl. CPC H10F 71/129; H10F 77/311

(57) ABSTRACT

Disclosed are a passivation method, a cell, and an auxiliary passivation device for implementing the passivation method to solve a problem of a gap between adjacent sheet-like materials when passivating to-be-passivated side surface of the sheet-like materials, causing process gas to wrap-around plating the sheet-like materials along the gap. The passivation method includes: placing a sheet-like material on a carrying device; covering at least one layer of protection film on a surface, away from the carrying device, of the sheet-like material; stacking a next sheet-like material on a side, away from the sheet-like material, of the protection film; and passivating to-be-passivated side surface of stacked sheet-like materials. The wrap-around plate with the process gas on the sheet-like material along the gap between adjacent sheet-like materials during passivation may be avoided.

### CROSS-REFERENCE TO RELATED APPLICATIONS

This present disclosure claims priority to Chinese Patent Application No. 202410245192.6, filed on Mar. 4, 2024, which is incorporated herein by reference in its entirety.

### TECHNICAL FIELD

The present disclosure relates to the field of cell technologies, and in particular, to a passivation method, a cell, and an auxiliary passivation device for implementing a passivation method.

### BACKGROUND

When passivating to-be-passivated side surface of sheet-like materials, a plurality of sheet-like materials are stacked next to each other, with to-be-passivated side surface exposed to the process gas.

However, a front surface and a back surface of the sheet-like materials include grid lines. The grid lines have a certain height in the thickness direction of the sheet-like materials, resulting in gaps between adjacent sheet-like materials, and causing the process gas to wrap-around plate the sheet-like materials along the gaps between adjacent sheet-like materials. Excess film layers on surfaces not to be passivated of the sheet-like materials are generated, and performance of the sheet-like materials is affected.

### SUMMARY

The present disclosure provides a passivation method. The passivation method includes: placing a sheet-like material on a carrying device, where the carrying device is configured to carry the sheet-like material for bringing it into a passivation device for passivation, the sheet-like material is configured to form a cell, and at least one of a front surface and a back surface of the sheet-like material comprises a grid line; covering at least one layer of protection film on a surface, away from the carrying device, of the sheet-like material; stacking a next sheet-like material on a side, away from the sheet-like material, of the protection film, where a to-be-passivated side surface of the sheet-like material and a to-be-passivated side surface of the next sheet-like material are located on a same side, and the protection film fills a gap between adjacent sheet-like materials; and passivating to-be-passivated side surface of stacked sheet-like materials.

### BRIEF DESCRIPTION OF THE DRAWINGS

To make aforementioned as well as other objectives, features, and advantages of the present disclosure more apparent, a more detailed description of embodiments of the present disclosure is given with reference to the drawings. The drawings are intended to provide further understanding of the embodiments of the present disclosure and constitute a part of the specification, used to explain the present disclosure together with the embodiments of the present disclosure, and do not constitute a limitation on the present disclosure. In the drawings, the same reference numerals generally represent the same components or steps.

FIG. 1 is a structural schematic diagram of stacked sheet-like materials.

FIG. 2 is a partially enlarged view at A in FIG. 1.

FIG. 3 is a flowchart of a passivation method according to an embodiment of the present disclosure.

FIG. 4 is a schematic diagram of an application scenario applicable to a carrying device according to an embodiment of the present disclosure.

FIG. 5 is a structural schematic diagram of a protection film and a sheet-like material according to an embodiment of the present disclosure.

FIG. 6 is a structural schematic diagram of a protection film and a sheet-like material according to another embodiment of the present disclosure.

FIG. 7 is a flowchart of a passivation method according to another embodiment of the present disclosure.

FIG. 8 is a flowchart of a passivation method according to still another embodiment of the present disclosure.

FIG. 9 is a schematic diagram of an application scenario of a carrying device according to an embodiment of the present disclosure.

FIG. 10A is a schematic diagram of an application scenario of a carrying device according to another embodiment of the present disclosure.

FIG. 10B is an application scenario of a carrying device according to another embodiment of the present disclosure.

FIG. 11 is a partially enlarged view at B in FIG. 10A according to an embodiment of the present disclosure.

FIG. 12 a flowchart of a passivation method according to yet another embodiment of the present disclosure.

FIG. 13 is a schematic diagram of an application scenario of a carrying device according to still another embodiment of the present disclosure.

FIG. 14 is a flowchart of a passivation method according to still yet another embodiment of the present disclosure.

FIG. 15 is a schematic diagram of principle of forming a sheet-like material according to an embodiment of the present disclosure.

FIG. 16 is a structural schematic diagram of a cell according to an embodiment of the present disclosure.

### DETAILED DESCRIPTION OF THE EMBODIMENTS

The technical schemes in the embodiments of the present disclosure will be described clearly and completely below in combination with the accompanying drawings in the embodiments of the present disclosure. Obviously, the described embodiments are only a part of the embodiments of the present disclosure, not all of the embodiments. Based on the embodiments in the present disclosure, all other embodiments obtained by those skilled in the art without creative efforts shall fall within the protection scope of the present disclosure.

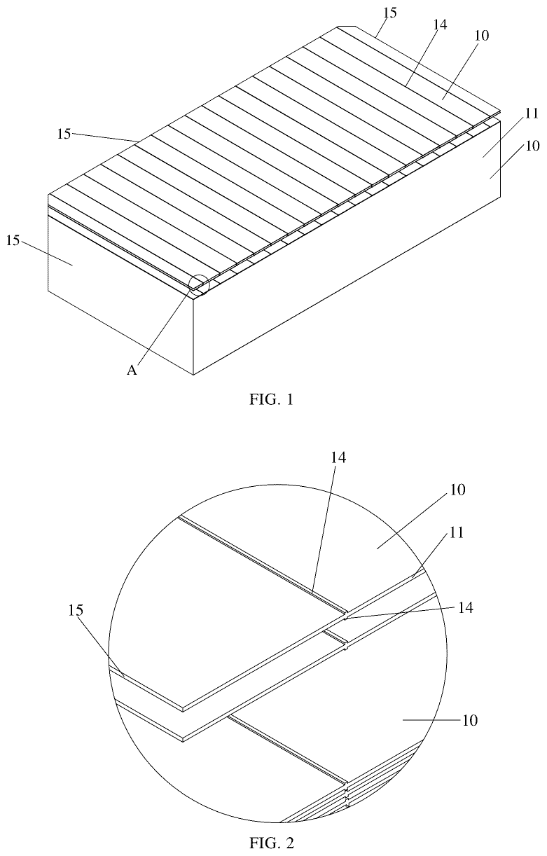

FIG. 1 is a structural schematic diagram of stacked sheet-like materials. FIG. 2 is a partially enlarged view at A in FIG. 1.

As shown in FIG. 1 and FIG. 2, when passivating a to-be-passivated side surface 11 of a sheet-like material 10, a plurality of sheet-like materials 10 are stacked next to each other, and the to-be-passivated side surface 11 is exposed to process gas.

However, a plurality of grid lines 14 are arranged on a front surface 12 and a back surface 13 of the sheet-like material 10. The plurality of grid lines 14 extend from the surface of the sheet-like material 10 for forming a gap between adjacent sheet-like materials 10 when stacking the plurality of sheet-like materials 10, and the sheet-like material 10 would form a wrap-around contact by the process gas introduced into the gap. The performance of the sheet-like material 10 would be influenced if the sheet-like material 10 formed a wrap-around contact.

To solve the above issues, the present disclosure provides a passivation method, a cell, and an auxiliary passivation device for implementing a passivation method. The following is a detailed description of the specific steps of the passivation method, as well as the specific structure of the cell and the auxiliary passivation device for implementing a passivation method with reference to the drawings and specific embodiments.

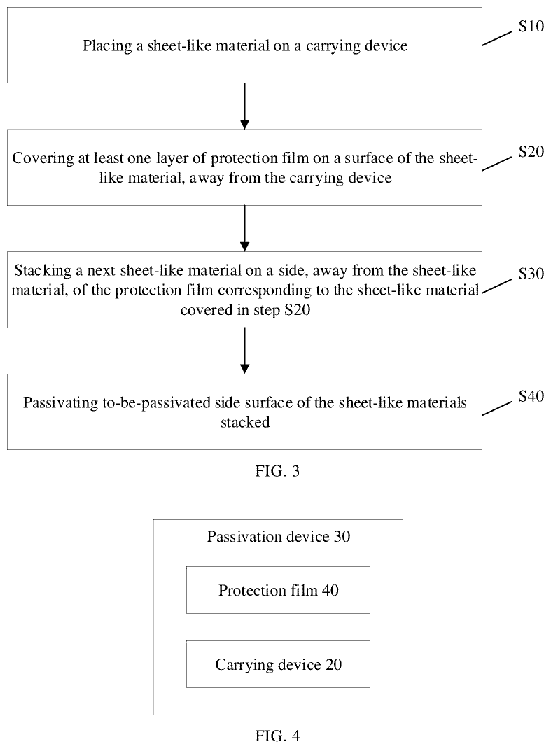

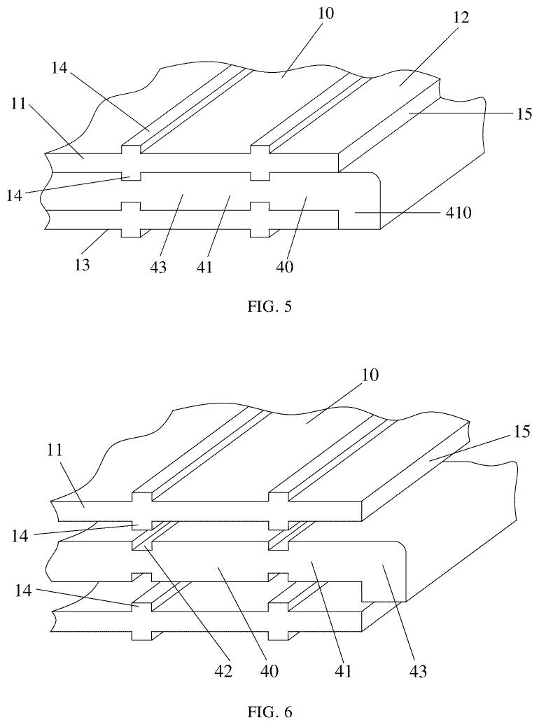

FIG. 3 is a flowchart of a passivation method according to an embodiment of the present disclosure. FIG. 4 is a schematic diagram of an application scenario applicable to a carrying device according to an embodiment of the present disclosure. FIG. 5 is a structural schematic diagram of a protection film and a sheet-like material according to an embodiment of the present disclosure. FIG. 6 is a structural schematic diagram of a protection film and a sheet-like material according to another embodiment of the present disclosure.

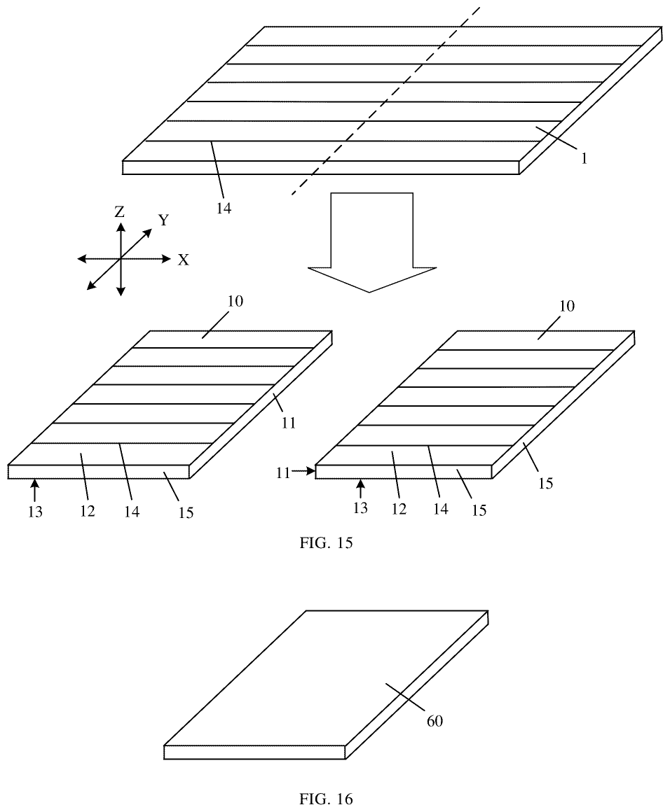

As shown in FIG. 3 to FIG. 6, the passivation method provided in this embodiment is configured to passivate the to-be-passivated side surface 11 of the plurality of sheet-like materials 10 stacked. The sheet material 10 is used to form cells (not shown in the figure). At one grid line 14 is arranged on the surface of the sheet-like material 10. The grid line 14 could arranged on a front surface 12 or a back surface 13 of the sheet-like material 10. It is also possible to arrange one grid line 14 on each of the front surface 12 and the back surface 13. FIG. 15 is a schematic diagram of principle of forming a sheet-like material according to an embodiment of the present disclosure. As shown in FIG. 15, the sheet-like material 10 extends approximately along a plane parallel to a first direction X and a second direction Y, and the grid line 14 extends along the first direction X. The to-be-passivated side surface 11 of the sheet-like material 10 is located at an end of the sheet-like material 10 in the first direction X. In other words, the front surface 12 and the back surface 13 extend approximately along the plane parallel to the first direction X and the second direction Y. The to-be-passivated side surface 11 extends approximately along a plane parallel to the second direction Y and a third direction Z. The third direction Z is perpendicular to the first direction X and the second direction Y. The size of the to-be-passivated side surface 11 in the third direction Z is approximately equal to the thickness of the sheet-like material 10. The sheet-like materials 10 are stacking along the third direction Z. The to-be-passivated side surface 11 is a section plane formed by cutting the original sheet-like material 1. The sheet-like material 10 is obtained by cutting the original sheet-like material 1 along the dashed line in FIG. 15. The sheet-like material 10 includes a front surface 12 (i.e., upper surface), a back surface 13 (i.e., lower surface), a to-be-passivated side surface 11, and a non-passivated side surface 15.

The passivation method includes the following steps.

Step S10: Placing a sheet-like material 10 on a carrying device 20.

The carrying device 20 is configured to carry the sheet-like material 10 for bringing it into a passivation device 30 for passivation.

Specifically, the sheet-like material 10 may include a silicon wafer, a wafer, a cell, and so on. The sheet-like material 10 may be a raw material or semi-manufactured product configured to form a cell. The front surface 12 of the sheet-like material 10 may include a side surface, coated with an anti-reflective layer, of the silicon wafer. The back surface 13 of the sheet-like material 10 may include a surface opposite to the front surface 12. In some embodiments, the front surface 12 of the sheet-like material 10 is not provided with a grid line, for example, the sheet-like material 10 configured to form a back contact battery.

The carrying device 20 may be any device capable of carrying the sheet-like material 10. As shown in FIG. 4, the carrying device 20 may further include a device for carrying the sheet-like material 10 when passivating the to-be-passivated side surface 11 in the passivation device 30. The passivation device 30 may include a passivation reaction furnace, a vapor deposition device, and so on.

Step S20: Covering at least one layer of protection film 40 on a surface of the sheet-like material 10, away from the carrying device 20.

Specifically, the protection film 40 may be a membranous object. The protection film 40 may be covered on the surface of the sheet-like material 10 by placing, coating, laying, and so on.

Step S30: Stacking a next sheet-like material 10 on a side, away from the sheet-like material 10, of the protection film 40 corresponding to the sheet-like material 10 covered in step S20. The to-be-passivated side surface 11 of the sheet-like material 10 and the to-be-passivated side surface 11 of the next sheet-like material 10 are located on a same side.

Specifically, one or more layers of protection film 40 may be disposed between adjacent sheet-like materials 10. The protection film 40 may fill or cover a gap between adjacent sheet-like materials 10. For example, as shown in FIG. 5 and FIGS. 6, the protection film 40 includes a protection film body 41, and at least one groove 42 on the side contacted with the sheet-like material 10. The groove 42 may be configured to accommodate the grid line 14 on the side, contacted with the protection film 40, of the sheet-like material 10. The protection film body 41 may fill or cover the gap between adjacent sheet-like materials 10.

Exemplarily, the surface, which includes the grid lines 14 and is configured to contact the sheet-like material 10, of the protection film 40 includes a plurality of grooves 42. The number of the grooves 42 is equal to the number of the grid lines 14 in contact with the sheet-like material 10. The shape of the groove 42 is adapted to the shape of the grid line 14. For example, the shape of the grid line 14 is a long strip, and the shape of the groove 42 is a long strip. The width of the groove is equal to the width of the grid line 14, the depth of the groove is equal to the height of the grid line 14, and the length of the groove 42 is equal to the length of the grid line 14.

Exemplarily, the surface of the protection film 40 may have no grooves 42. Specifically, the material of the protection film 40 may be produced by an elastic material. After a surface of the sheet-like material 10 having the grid line 14 is in contact with the protection film 40, the grid lines 14 may be compressed against the protection film 40 so that the grid lines 14 are embedded in the protection film 40. In other words, before the protection film 40 contacts with the sheet-like material 10, there may be no grooves on the surface of the protection film 40; however, after the protection film 40 contacts with the sheet-like material 10, the grid lines 14 are embedded in the protection film 40, forming the grooves 42 on the protection film 40.

Exemplarily, a plurality of protection films 40 are disposed between adjacent sheet-like materials 10, and the shape of the protection films 40 may be the same or different. For example, the surface of the sheet-like material 10, away from the carrying device 20, may be either the front surface 12 or the back surface 13 of the sheet-like material 10. The area of the protection film 40 may be greater than or equal to the area of the front surface 12 or the back surface 13 of the sheet-like material 10.

Step S40: Passivating to-be-passivated side surface 11 of the sheet-like materials 10 stacked.

Exemplarily, the to-be-passivated side surface 11 of each of the sheet-like materials 10 may include a cross section or a cut section generated on the side of the sheet-like material 10 when forming the sheet-like material 10.

Exemplarily, for the sheet-like materials 10 stacked named as a stacked sheet-like materials 10, at least one layer of protection film 40 may be set between adjacent sheet-like materials 10 with or without the grid lines 14 on the opposite surfaces of the adjacent sheet-like materials 10. In some embodiments, the stacked sheet-like materials 10 may include stacking the front surfaces 12 of the stacked sheet-like materials 10 in the same direction. In some embodiments, the stacked sheet-like materials 10 may include that the stacked sheet-like materials 10 are horizontally stacked.

According to the passivation method provided in this embodiment, by providing the protection film 40 between the adjacent sheet-like materials 10, which fills or covers the gap between adjacent sheet-like materials 10, the wrap-around plate with the process gas on the sheet-like material 10 along the gap between adjacent sheet-like materials 10 during passivation may be avoided, thereby improving the performance of the passivated sheet-like materials 10.

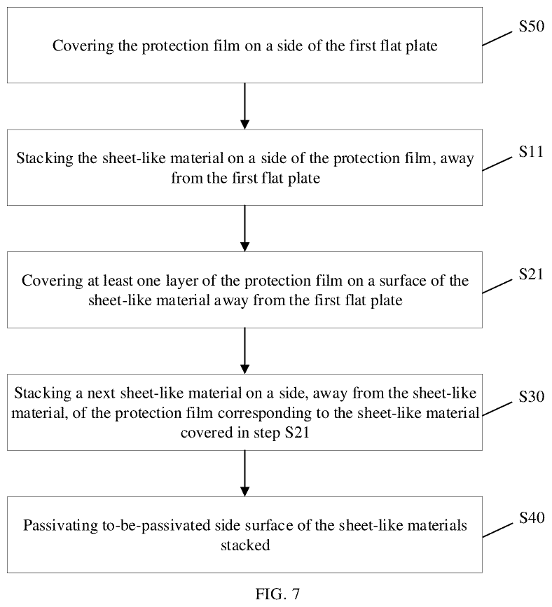

FIG. 7 is a flowchart of a passivation method according to another embodiment of the present disclosure. The embodiment shown in FIG. 7 is an extension of the embodiment shown in FIG. 3, and differences between the embodiment shown in FIG. 7 and the embodiment shown in FIG. 3 are introduced bellow, and the similarities are not repeated.

The carrying device 20 includes a first flat plate. The first flat plate may include a plate-shaped component. The first flat plate may be configured to carry the stacked sheet-like materials 10 when passivating the to-be-passivated side surface 11 in the passivation device 30. Exemplarily, when passivating the to-be-passivated side surface 11 in the passivation device 30, the first flat plate is disposed parallel to the sheet-like materials 10 and is located at the bottom of the stacked sheet-like materials 10. Exemplarily, the side, near the sheet-like material 10, of the first flat plate may include a plane.

As shown in FIG. 7, before the step S10: Placing a sheet-like material 10 on a carrying device 20, the passivation method further includes step S50: Covering the protection film 40 on a side of the first flat plate.

Step S10: Placing a sheet-like material 10 on a carrying device 20, includes step S11: Stacking the sheet-like material 10 on a side of the protection film 40, away from the first flat plate.

Exemplarily, the surface, near the first flat plate, of the sheet-like material 10 may be provided with at least one of the grid lines 14.

Step S20: Covering at least one layer of protection film 40 on a surface of the sheet-like material 10, away from the carrying device 20, includes step S21: Covering at least one layer of the protection film 40 on a surface of the sheet-like material 10 away from the first flat plate. Step S30: Stacking a next sheet-like material 10 on a side, away from the sheet-like material 10, of the protection film 40 corresponding to the sheet-like material 10 covered in step S20, is further configured as: Stacking a next sheet-like material 10 on a side, away from the sheet-like material 10, of the protection film 40 corresponding to the sheet-like material 10 covered in step S21.

According to the passivation method provided in this embodiment, the carrying device 20 includes the first flat plate. When passivating the to-be-passivated side surface 11 in the passivation device 30, the first flat plate may carry the sheet-like material 10. By disposing the protection film 40 between the first flat plate and the sheet-like material 10 adjacent to the first flat plate, the protection film 40 may fill or cover the gap between the first flat plate and the sheet-like material 10 adjacent to the first flat plate, thereby avoiding the process gas from wrap-around plating the sheet-like material 10 along the gap between the first flat plate and the sheet-like material 10 adjacent to the first flat plate during passivation of the to-be-passivated side surface 11 of the sheet-like material 10, thereby further improving the performance of the passivated sheet-like materials 10.

In some embodiments, before step S40: Passivating to-be-passivated side surface 11 of stacked sheet-like materials 10, the passivation method further includes: Covering at least one layer of the protection film 40 on a side, away from the first flat plate, of the sheet-like material 10 farthest from the first flat plate. This may prevent the surface of the sheet-like material 10, which is farthest from the first flat plate, from being plated with process gas on the side away from the first flat plate.

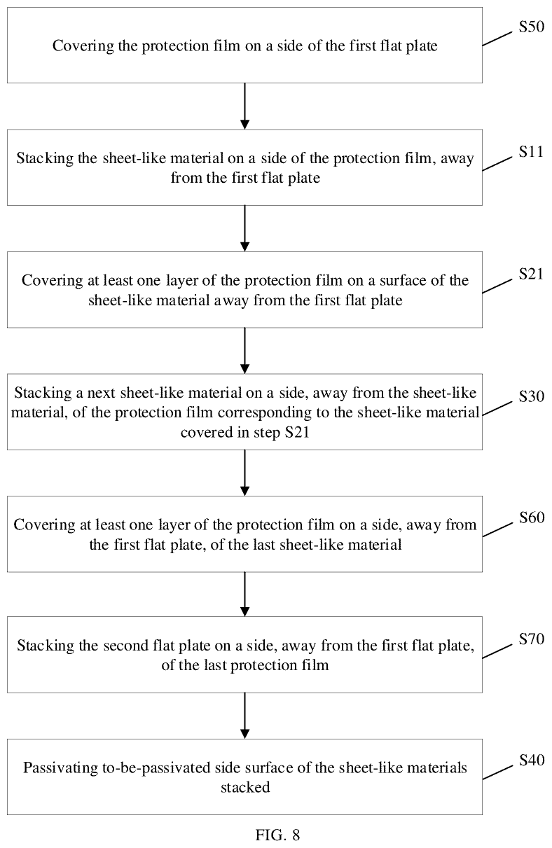

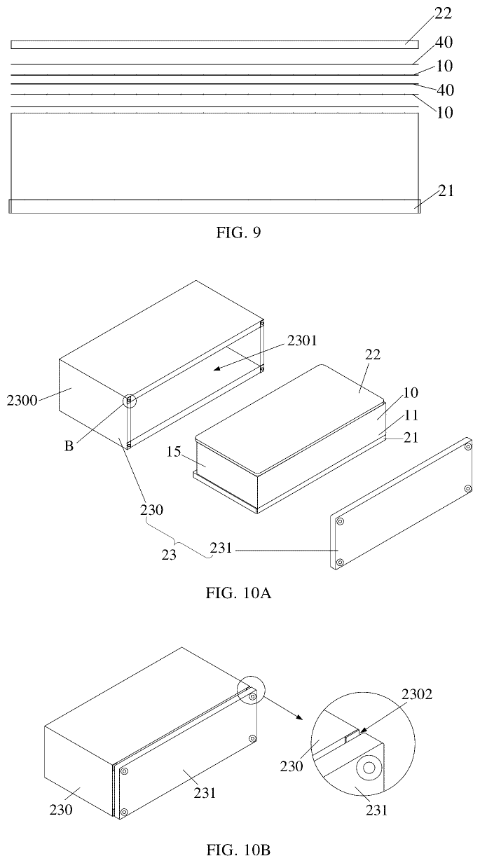

FIG. 8 is a flowchart of a passivation method according to still another embodiment of the present disclosure. The embodiment shown in FIG. 8 is an extension of the embodiment shown in FIG. 7, and differences between the embodiment shown in FIG. 8 and the embodiment shown in FIG. 7 are introduced bellow, and the similarities are not repeated. FIG. 9 is a schematic diagram of an application scenario of a carrying device according to an embodiment of the present disclosure.

As shown in FIG. 9, the carrying device 20 further includes a second flat plate 22. The second flat plate 22 may be configured to be sent into the passivation device 30 together with the sheet-like material 10. The second flat plate 22 may include a plate-shaped component. The side, near the sheet-like material 10, of the second flat plate 22 may include a plane. In FIG. 9, in order to display the second flat plate 22, the sheet-like material 10, and the protection film 40, the second flat plate 22, partial sheet-like material 10, and partial protection film 40 are displayed in the form of an exploded view. In practical applications, the second flat plate 22, the sheet-like material 10, and the protection film 40 are compressed.

As shown in FIG. 8, before step S40: Passivating to-be-passivated side surface 11 of stacked sheet-like materials 10, the passivation method further includes the following steps.

Step S60: Covering at least one layer of the protection film 40 on a side, away from the first flat plate 21, of the last sheet-like material 10.

Exemplarily, the last sheet-like material 10 may be the sheet-like material 10 farthest from the first flat plate 21.

Step S70: Stacking the second flat plate 22 on a side, away from the first flat plate 21, of the last protection film 40.

Exemplarily, the last protection film 40 may be the protection film 40 on the side, away from the first flat plate 21, of the last sheet-like material 10.

The second flat plate 22 is disposed opposite to the first flat plate 21 to form an accommodation space. The accommodation space is configured to accommodate the stacked sheet-like materials 10. Exemplarily, the second flat plate 22 is disposed parallel to the sheet-like material 10 and the first flat plate 21. Exemplarily, the second flat plate 22 may be configured to compress the staked sheet-like materials 10 and the protection film 40, or to cooperate with the first flat plate 21 to compress the staked sheet-like materials 10 and the protection film 40, so that the first flat plate 21, the second flat plate 22, and the sheet-like material 10 and the protection film 40 between the first flat plate 21 and the second flat plate 22 are in close contact, avoiding the process gas from wrap-around plating the sheet-like material 10 along the gap between the first flat plate 21, the second flat plate 22, and the sheet-like material 10 between the first flat plate 21 and the second flat plate 22, thereby further improving the performance of the passivated sheet-like materials 10.

According to the passivation method provided in this embodiment, the second flat plate 22 and the first flat plate 21 form the accommodation space to accommodate the stacked sheet-like materials 10; and the protection film is disposed between the last sheet-like material 10 and the second flat plate 22, the protection film 40 may fill or cover the gap between the last sheet-like material 10 and the second flat plate 22, avoiding the process gas from wrap-around plating the sheet-like material 10 through the gap between the sheet-like material 10 and the second flat plate 22, thereby further improving the performance of the passivated sheet-like material 10.

FIG. 10A is a schematic diagram of an application scenario of a carrying device according to another embodiment of the present disclosure. FIG. 10B is an application scenario of a carrying device according to another embodiment of the present disclosure. FIG. 11 is a partially enlarged view at B in FIG. 10A.

As shown in FIG. 10A and FIG. 10B, the carrying device 20 includes: a first flat plate 21, a second flat plate 22, and a film box 23. The film box 23 includes a box body 230 and a box cover 231. The box cover 231 is detachably connected to the box body 230. The box body 230 includes an accommodation chamber 2301, and the accommodation chamber 2301 is configured to accommodate the first plate 21, the second plate 22, and a sheet-like material 10 and a protection film 40 accommodated between the first flat plate 21 and the second flat plate 22.

As shown in FIG. 10B, a gap 2302 is provided between the box body 230 and the box cover 231 when the box body 230 is fastened with the box cover 231. The gap 2302 is configured as an inlet for process gas. When the passivation device 30 passivates the to-be-passivated side surface 11, the process gas enters the film box through the gap 2302. When the sheet-like material 10 is accommodated in the accommodation chamber, the to-be-passivated side surface 11 of the sheet-like material 10 is placed towards the side, where the gap 2302 is disposed, of the film box 23.

In this embodiment, the sheet-like material 10 further includes at least one non-passivated side surface 15. The non-passivated side surface 15 includes the side of the sheet-like material 10 that does not need to be passivated. The box body 230 is composed of a plurality of box boards 2300. The box board 2300 of the box body 230 is located on a side facing the non-passivated side surface 15 of the sheet-like material 10, so that the box board 2300 may cover the non-passivated side surface 15 of the sheet-like material 10, which may avoid the process gas from entering the box body 230 through the gap 2302 and wrap-around plating the non-passivated side surface 15 of the sheet-like material 10.

As shown in FIG. 10A, FIG. 10B and FIG. 11, the box body 230 includes a protrusion 2301 on a side, which is configured to fasten with the box cover 231, of the box body 230. The protrusion 2301 may create the gap 2302 when the box body 230 and the box cover 231 is fastened; and a size of the protrusion 2301 in a direction perpendicular to the box cover 231 is equal to a size of the gap 2302 in the direction perpendicular to the box cover 231. The amount of the process gas entering the film box 23 may be adjusted by adjusting the width of the gap 2302. In some embodiments, there is a gap between the non-passivated side surface 15 of the sheet-like material 10 and the box board 2300; by reducing the width of the gap 2302 between the box body 230 and the box cover 231 when they are fastened, the wrap-around plate with the process gas on the non-passivated side surface 15 through the gap between the non-passivated side surface 15 of the sheet-like material 10 and the box board 2300.

In some embodiments, before step S40: Passivating to-be-passivated side surface 11 of stacked sheet-like materials 10, the passivation method further includes: sending the carrying device 20 with the stacked sheet-like materials 10 into the passivation device 30.

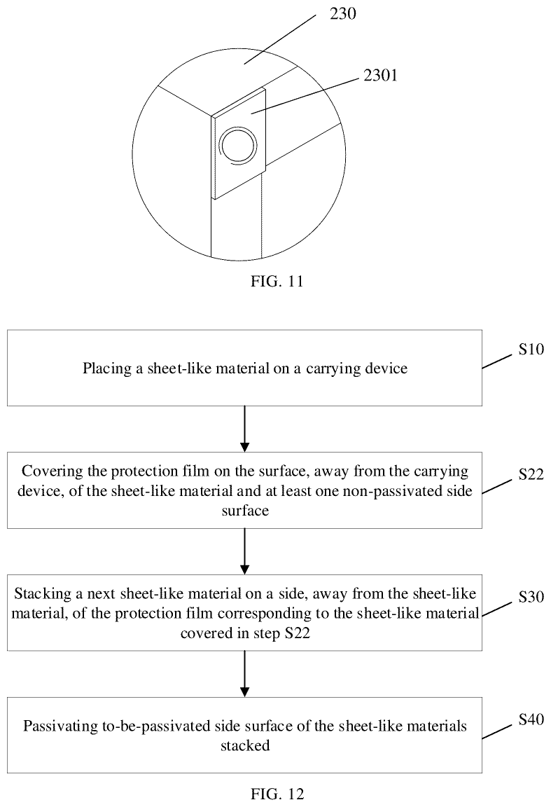

FIG. 12 a flowchart of a passivation method according to yet another embodiment of the present disclosure. The embodiment shown in FIG. 12 is an extension of the embodiment shown in FIG. 3, and differences between the embodiment shown in FIG. 12 and the embodiment shown in FIG. 3 are introduced bellow, and the similarities are not repeated.

In this embodiment, the sheet-like material 10 is further provided with at least one non-passivated side surface 15.

Step S20: Covering at least one layer of protection film 40 on a surface, away from the carrying device 20, of the sheet-like material 10, includes step S22: Covering the protection film 40 on the surface, away from the carrying device 20, of the sheet-like material 10 and at least one non-passivated side surface 15. Step S30: Stacking a next sheet-like material 10 on a side, away from the sheet-like material 10, of the protection film 40 corresponding to the sheet-like material 10 covered in step S20, is further configured as: Stacking a next sheet-like material 10 on a side, away from the sheet-like material 10, of the protection film 40 corresponding to the sheet-like material 10 covered in step S22.

Exemplarily, the protection film 40 may cover the non-passivated side surface 15 of one sheet-like material 10 or adjacent sheet-like materials 10. For example, as shown in FIG. 5, the protection film 40 includes an extension portion 410 in a thickness direction of the protection film 40 at the edge of the protective film body 41. The size, in a thickness direction of the protection film 40, of the extension portion 410 is greater than or equal to a thickness of at least one sheet-like material 10. The extension portion 410 of the protection film 40 may cover the non-passivated side surface 15 of the sheet-like material 10.

According to the passivation method provided in this embodiment, the protection film 40 may cover the surface, away from the carrying device 20, of the sheet-like material 10, as well as at least one non-passivated side surface 15. That is, the protection film may further cover the non-passivated side surface 15 of the sheet-like material 10, avoiding the process gas from wrap-around plating the non-passivated side surface 15 of the sheet-like material 10, and is conducive to simplifying the structure of the carrying device 20 and reducing the load of a device for transporting the carrying device 20. Exemplarily, the box board 2300, facing the non-passivated side surface 15 of the sheet-like material 10, of the box body 230 may not be disposed. In some application scenarios, when the passivation device 30 passivates the to-be-passivated side surface 11, it is necessary to preheat the sheet-like material 10, and the preheating time for the sheet-like material 10 may be shorten by simplifying the structure of the carrying device 20, thereby improving production efficiency.

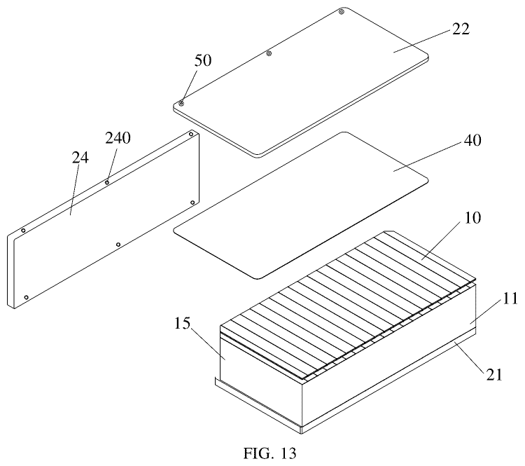

FIG. 13 is a schematic diagram of an application scenario of a carrying device according to still another embodiment of the present disclosure.

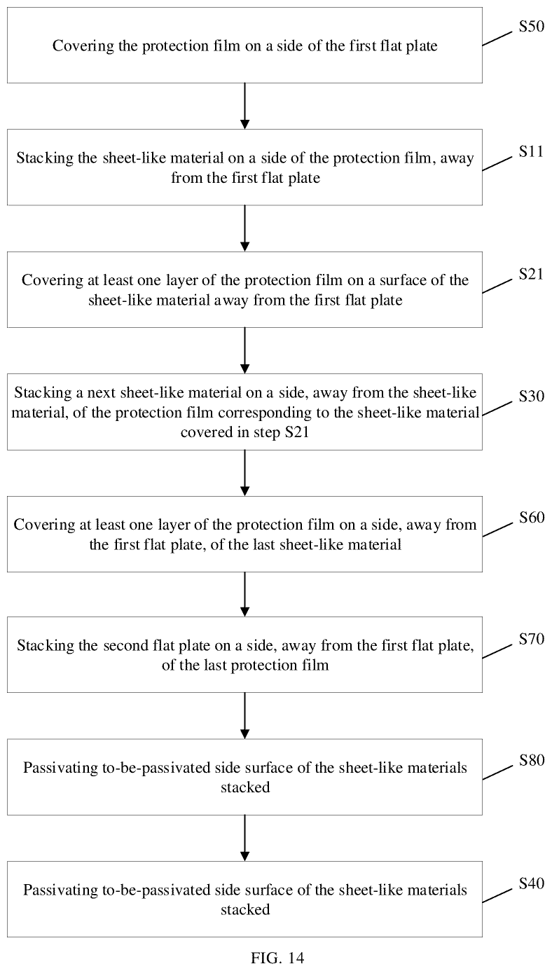

FIG. 14 is a flowchart of a passivation method according to still yet another embodiment of the present disclosure. The embodiment shown in FIG. 14 is an extension of the embodiment shown in FIG. 8, and differences between the embodiment shown in FIG. 14 and the embodiment shown in FIG. 8 are introduced bellow, and the similarities are not repeated.

As shown in FIG. 13, the carrying device 20 further includes a side plate 24.

Before step S40: Passivating to-be-passivated side surface 11 of stacked sheet-like materials 10, the passivation method further includes step S80: Connecting the side plate 24 to the first flat plate 21 and the second flat plate 22 separately.

At least one of the first flat plate 21 and the second flat plate 22 is supported by the side plate 24. When the carrying device 20 with several sheet-like materials 10 is moved, relative movement between the first flat plate 21 and the second flat plate 22 may be prevented. When relative movement occurs between the protection film 40 and the sheet-like material 10, the damage caused by the protective film 40 to the gap filling or blocking between the first flat plate 21, the multi sheet-like material 10, and the second flat plate 22 is prevented, and the structural stability of the carrying device 20 is improved.

Exemplarily, the side plate 24 is detachably connected to at least one of the first flat plate 21 and the second flat plate 22. The shape of the side plate 24 may be set according to requirements. In some embodiments, the side plate 24 may be configured to cover the non-passivated side surface 15 when passivating the to-be-passivated side surface 11 of the sheet-like material 10. In other embodiments, the first plate 21, the second plate 22, the side plate 24, and the stacked sheet-like material 10 are all fed into the film box 23 and carried into the passivation device 30 by the film box 23.

In some embodiments, the protection film 40 may cover the surface, away from the carrying device 20, of the sheet-like material 10, as well as all non-passivated side surface 15. Due to the non-passivated side surface of the sheet-like material 10 being protected by the protection film 40, as shown in FIG. 13, the carrying device 20 may only include the first flat plate 21, the second flat plate 22, and the side plate 24 connected to the first flat plate 21 and the second flat plate 22 separately, and the film box 23 is not necessary. This may further simplify the structure of the carrying device 20, reduce the load on the device for transporting the carrying device 20, shorten the preheating time of the passivation device 30 for the sheet-like material 10, and improve production efficiency. In this embodiment, the side plate 24 does not need to cover the non-passivated side surface 15. The shape of the side plate 24 may be rod shaped, column shaped, plate shaped, and so on, as long as it may support at least one of the first flat plate 21 and the second flat plate 22.

In some embodiments, the to-be-passivated side surface 11 of the sheet-like material 10 and the to-be-passivated side surface 11 of the next sheet-like material 10 are located on a same plane. This setting may avoid the differences in passivation conditions caused by the irregular of the sheet-like material 10, which is beneficial for improving the uniformity of passivation effect, and may also avoid the situation where the protection film 40 does not fully cover the front surface or the back surface of the sheet-like material 10, leading to wrap-around plate.

Exemplarily, the to-be-passivated side surface 11 of stacked sheet-like materials 10 may all be located on the same plane.

In some embodiments, the protection film 40 includes a film layer 43 with elasticity in a thickness direction to have the grid line 14 of the sheet-like material 10 embedded in the protection film 40. Since the protection film 40 includes the film layer 43 with elasticity in the thickness direction, as shown in FIG. 5, the adjacent sheet-like materials 10 may compress and deform the protection film 40, so that the grid line 14 of the sheet-like material 10 may be embedded in the protection film 40, allowing the protection film 40 to fill or cover the gap between adjacent sheet-like materials 10. Exemplarily, when passivating the to-be-passivated side surface 11 of the sheet-like material 10, the protection film 40 covering the non-passivated surface of the sheet-like material 10 may be compressed by the sheet-like material 10 and the sheet-like material 10 stacked above it.

In some embodiments, the protection film 40 may further include a flexible film layer. The flexible film layer is easy to be bent and shaped, and it is easy to fit surfaces at different angles. When covering the surface away from the carrying device 20 and at least one side surface not to be passive 15 of the sheet-like material 10, it may better fit the side surface not to be passive 15. Exemplarily, the flexible film covering the non-passivated side surface 15 may be naturally sagging or the edge may be clamped. In some embodiments, the protection film 40 may have elasticity in the thickness direction and be flexible.

In some embodiments, the material of the protection film includes one or more combinations of polyimide, mica polybenzimidazole, and glass fiber.

The above provides a detailed description of the embodiments of the passivation method, and the following would describe in detail an embodiment of a cell. It should be understood that the description of the embodiments of the passivation method corresponds to the description of the embodiment of the cell. Therefore, the parts that are not described in detail may refer to the embodiments of the passivation method above.

An embodiment of the present disclosure provides a cell. FIG. 16 is a structural schematic diagram of a cell according to an embodiment of the present disclosure. As shown in FIG. 16, the cell 60 is obtained based on a sheet-like material 10 prepared by a passivation method according to any of the above embodiments. Exemplarily, the cell 60 includes a photovoltaic cell.

During the preparation process of the cell provided in this embodiment, a protection film 40 is disposed between adjacent sheet-like materials 10, which fills or covers the gap between the adjacent sheet materials 10, thereby avoiding the process gas from wrap-around plating the sheet-like material 10 along the gap between the adjacent sheet materials 10, thereby improving the performance of the passivated sheet-like materials 10, and further improving the performance of the prepared cell.

The above provides a detailed description of the embodiments of the passivation method, and the following would describe in detail an embodiment of an auxiliary passivation device for implementing a passivation method. It should be understood that the description of the embodiments of the passivation method corresponds to the description of the embodiment of the auxiliary passivation device for implementing a passivation method. Therefore, the parts that are not described in detail may refer to the embodiments of the passivation method above.

An embodiment of the present disclosure provides an auxiliary passivation device for implementing a passivation method. The auxiliary passivation device for implementing a passivation method is applied to implement a passivation method described in any of the above embodiments. The passivation method is configured to passivate the to-be-passivated side surface 11 of stacked sheet-like materials 10. The sheet-like material 10 is configured to prepare a cell. At least one of the front surface and back surface of the sheet-like material 10 includes a grid line 14.

The auxiliary passivation device for implementing a passivation method includes a carrying device 20 and at least one layer of protection film 40. The carrying device 20 is configured to carry the sheet-like material 10 for bringing it into a passivation device 30 for passivation. And at least one layer of protection film 40 is configured to fill a gap between adjacent sheet-like materials 10.

In the application of the auxiliary passivation device for implementing a passivation method provided in this embodiment, the protection film 40 is disposed between the adjacent sheet-like materials 10, which fills or covers the gap between the adjacent sheet materials 10, thereby avoiding the process gas from wrap-around plating the sheet-like material 10 along the gap between the adjacent sheet materials 10, thereby improving the performance of the passivated sheet-like materials 10, and further improving the performance of the prepared cell.

Exemplarily, the carrying device 20 may further include a device for carrying the sheet-like material 10 when passivating the to-be-passivated side surface 11 in the passivation device 30. Exemplarily, the carrying device 20 may carry one or more sets of stacked protection films 40 and sheet-like materials 10.

In some embodiments, as shown in FIG. 13, the sheet-like material 10 is further provided with at least one non-passivated side surface 15. And the number of the protection film 40 may be multiple.

The carrying device 20 includes a first flat plate 21, a second flat plate 22, and a side plate 24. The first flat plate 21 is configured to carry the sheet-like material 10. The second flat plate 22 is disposed opposite to the first flat plate 21 to form an accommodation space. The accommodation space is configured to accommodate the stacked sheet-like materials 10. The side plate 24 is detachably connected to the first flat 21 plate and the second flat plate 22.

The plurality of protection films 40 are disposed respectively between the first flat plate 21 and the sheet-like material 10, between the adjacent sheet-like materials 10, and between the sheet-like material 10 and the second flat plate, and covers at least one non-passivated side surface.

Exemplarily, the side plate 24 is detachably connected to at least one of the first flat plate 21 and the second flat plate 22. The disassembly and assembly of the side plate 24 with at least one of the first flat plate 21 and the second flat plate 22 may be achieved through manual or automated equipment. Exemplarily, as shown in FIG. 13, the side plate 24 includes threaded holes 240 on the surface connected to the first flat plate 21 and the second flat plate 22. The first flat plate 21 and the second flat plate 22 include through holes 50. The side plate 24, the first flat plate 21, and the second flat plate 22 may be fixed by screws (not shown in the figure) through the through holes 50 and the threaded holes, and further, the first flat plate 21 and the second flat plate 22 may be tightened to press the protection film 40 and the sheet-like material 10. Exemplarily, a spring is disposed between the side plate 24, the first flat plate 21, and the second flat plate 22, which are tightened by the spring, and the first flat plate 21 and the second flat plate 22 are pressed against the protection film 40 and the sheet-like material 10. Exemplarily, the side plate 24 may be configured to provide a guide groove in the thickness direction of the sheet-like material 10, so that the first flat plate 21 or the second flat plate 22 slides along the guide groove; for example, the second flat plate 22 is located above the first flat plate 21, and the protection film 40 and the sheet-like material 10 are compressed through the self-weight of the second flat plate 22.

The carrying device 20 provided in this embodiment includes high structural stability, making it easy to send the sheet-like material 10 into the passivation device 30 for passivation. It may also prevent relative movement between the first flat plate 21 and the second flat plate 22 when the carrying device 20 carrying sheet-like materials 10 is moved, causing relative movement between the protection film 40 and the sheet-like material 10, and damaging the filling or covering of the gaps between the protection film 40 and the first flat plate 21, the sheet-like materials 10, and the second flat plate 22.

Additionally, while the various steps of the method in the present disclosure are described in a particular order in the drawings, this does not require or imply that these steps must be performed in that specific order, or that all shown steps must be executed to achieve the desired results. Alternatively, some steps may be omitted, multiple steps may be combined into one step, and/or one step may be divided into multiple steps, and so on.

The basic principles of the present disclosure have been described above with specific embodiments. However, it should be noted that the advantages, benefits, and effects mentioned in the present disclosure are mere examples and not limitations. They should not be taken as essential features that must be possessed by each embodiment of the present disclosure. Additionally, the specific details disclosed above serve merely as illustrations and aids for understanding, and do not constitute limitations. These details do not restrict the necessity of implementing the present disclosure with the aforementioned specific details.

The block diagrams of devices, apparatuses, equipment, and systems involved in the present disclosure are provided as illustrative examples only and do not require or imply that the connections, arrangements, or configurations must be made in the manner shown in the block diagrams. As will be recognized by those skilled in the art, these devices, apparatuses, equipment, and systems may be connected, arranged, and configured in any manner. Terms such as “include”, “contain”, “have”, and so on are open-ended terms that mean “including but not limited to” and may be used interchangeably. The term “such as” used here refers to the phrase “such as but not limited to” and may be used interchangeably.

It should also be noted that in the devices, equipment, and methods of the present disclosure, various components or steps may be decomposed and/or recombined. Such decomposition and/or recombination should be considered as equivalent solutions of the present disclosure.

The above description of the disclosed aspects is provided to enable those skilled in the art to make or use the present disclosure. Various modifications to these aspects will be readily apparent to those skilled in the art, and the general principles defined here may be applied to other aspects without departing from the scope of the present disclosure. Therefore, the present disclosure is not intended to be limited to the aspects shown here, but should be given the widest scope consistent with the principles and novel features disclosed here.

The above description has been given for the purpose of illustration and description. Furthermore, this description is not intended to limit the embodiments of the present disclosure to the forms disclosed here. Although multiple example aspects and embodiments have been discussed above, those skilled in the art will recognize certain variations, modifications, alterations, additions, and sub-combinations thereof.

What is claimed is:

1. A passivation method, comprising:
placing a sheet-like material on a carrying device, wherein the carrying device is configured to carry the sheet-like material for bringing it into a passivation device for passivation, the sheet-like material is configured to form a cell, and at least one of a front surface and a back surface of the sheet-like material comprises a grid line;
covering at least one layer of protection film on a surface, away from the carrying device, of the sheet-like material;
stacking a next sheet-like material on a side, away from the sheet-like material, of the protection film, wherein a to-be-passivated side surface of the sheet-like material and a to-be-passivated side surface of the next sheet-like material are located on a same side, and the protection film fills a gap between adjacent sheet-like materials; and
passivating to-be-passivated side surface of stacked sheet-like materials.

2. The passivation method according to claim 1, wherein the carrying device comprises a first flat plate;
before the placing a sheet-like material on a carrying device, the passivation method further comprises:
covering the protection film on a side of the first flat plate;
wherein the placing a sheet-like material on a carrying device comprises:
stacking the sheet-like material on a side, away from the first flat plate, of the protection film; and
wherein the covering at least one layer of protection film on a surface, away from the carrying device, of the sheet-like material comprises:
covering at least one layer of the protection film on a surface, away from the first flat plate, of the sheet-like material.

3. The passivation method according to claim 2, wherein the carrying device further comprises a second flat plate; and
before the passivating to-be-passivated side surface of stacked sheet-like materials, the passivation method further comprises:
covering at least one layer of the protection film on a side, away from the first flat plate, of the last sheet-like material; and
stacking the second flat plate on a side, away from the first flat plate, of the protection film, wherein the last protection film is the protection film on the side, away from the first flat plate, of the last sheet-like material.

4. The passivation method according to claim 1, wherein the sheet-like material further comprises at least one non-passivated side surface; and
the covering at least one layer of protection film on a surface, away from the carrying device, of the sheet-like material comprises:
covering the protection film on the surface, away from the carrying device, of the sheet-like material and the at least one non-passivated side surface.

5. The passivation method according to claim 3, wherein the carrying device further comprises a side plate; and
before the passivating to-be-passivated side surface of stacked sheet-like materials, the passivation method further comprises:
connecting the side plate to the first flat plate and the second flat plate separately.

6. The passivation method according to claim 1, wherein the to-be-passivated side surface of the sheet-like material and the to-be-passivated side surface of the next sheet-like material are located on a same plane.

7. The passivation method according to claim 1, wherein the protection film comprises a film layer with elasticity in a thickness direction to have the grid line of the sheet-like material embedded in the protection film.

8. The passivation method according to claim 7, wherein the protection film further comprises a flexible film layer.

9. The passivation method according to claim 1, wherein a material of the protection film comprises one or more combinations of polyimide, mica polybenzimidazole, and glass fiber.

10. The passivation method according to claim 1, wherein the sheet-like material extends along a plane parallel to a first direction and a second direction, the grid line extends along the first direction, and the to-be-passivated side surface is located at an end of the sheet-like material in the first direction.

11. A cell, wherein the cell is obtained based on a sheet-like material prepared by the passivation method according to claim 1.

12. An auxiliary passivation device for implementing a passivation method, configured to passivate to-be-passivated side surface of stacked sheet-like materials through the passivation method, wherein the sheet-like material is configured to prepare a cell, and at least one of a front surface and a back surface of the sheet-like material comprises a grid line; and
the auxiliary passivation device for implementing the passivation method comprises:
a carrying device, configured to carry the sheet-like material for bringing it into a passivation device for passivation; and
at least one layer of protection film, configured to fill a gap between adjacent sheet-like materials.

13. The auxiliary passivation device for implementing the passivation method according to claim 12, wherein the sheet-like material comprises a to-be-passivated side surface, and a number of the protection film is multiple; and
the carrying device comprises:
a first flat plate, configured to carry the sheet-like material, and a plurality of protection films are disposed between the first flat plate and the sheet-like material, or between adjacent sheet-like materials respectively.

14. The auxiliary passivation device for implementing the passivation method according to claim 13, further comprising:
a second flat plate, disposed opposite to the first flat plate to form an accommodation space, wherein the accommodation space is configured to accommodate the stacked sheet-like materials, and the plurality of protection films are further disposed between the sheet-like material and the second flat plate; and
a side plate, detachably connected to the first flat plate and the second flat plate.

15. The auxiliary passivation device for implementing the passivation method according to claim 13, wherein the carrying device further comprises:
a box body, comprising an accommodation chamber, wherein the accommodation chamber is configured to accommodate the first flat plate, the second flat plate, and the sheet-like material and the protection film accommodated between the first flat plate and the second flat plate; and
a box cover, detachably connected to the box body.

16. The auxiliary passivation device for implementing the passivation method according to claim 15, wherein a gap is provided between the box body and the box cover when the box body is fastened with the box cover, the gap is configured as an inlet for process gas, and when the passivation device passivates the to-be-passivated side surface, the process gas enters the accommodation chamber through the gap.

17. The auxiliary passivation device for implementing the passivation method according to claim 16, wherein the box body comprises a protrusion on a side, configured to engage with the box cover, of the box body, to create the gap when the box body and the box cover is fastened; and
a size of the protrusion in a direction perpendicular to the box cover is equal to a size of the gap in the direction perpendicular to the box cover.

18. The auxiliary passivation device for implementing the passivation method according to claim 15, wherein the sheet-like material further comprises at least one non-passivated side surface; and
the box body comprises:
a plurality of box boards, and the plurality of box boards is configured to cover the at least one non-passivated side surface of the sheet-like material.

19. The auxiliary passivation device for implementing the passivation method according to claim 11, wherein the sheet-like material is further provided with at least one non-passivated side surface; and
the protection film comprises an extension portion, and the extension portion covers at least one non-passivated side surface.

20. The auxiliary passivation device for implementing the passivation method according to claim 19, wherein a size, in a thickness direction of the sheet-like material, of the extension portion is greater than or equal to a thickness of one piece of the sheet-like material.
